(19) United States
(12) Patent Application Publication
(10) Pub. No.: US 2025/0126807 A1
(43) Pub. Date: Apr. 17, 2025

(54) RESISTIVE MEMORY STRUCTURE

(71) Applicant: United Microelectronics Corp., Hsinchu (TW)

(72) Inventor: Ching-In Wu, Taipei City (TW)

(73) Assignee: United Microelectronics Corp., Hsinchu (TW)

(21) Appl. No.: 18/499,223

(22) Filed: Nov. 1, 2023

(30) Foreign Application Priority Data
Oct. 17, 2023 (TW) 112139635

(51) Int. Cl. H10B 63/00; H10N 70/00

(52) U.S. Cl. CPC H10B 63/30; H10N 70/821; H10N 70/841; H10N 70/8833

(57) ABSTRACT

A resistive memory structure including a transistor device and a resistive memory device is provided. The transistor device includes a gate. The resistive memory device is electrically connected to the gate of the transistor device.

### CROSS-REFERENCE TO RELATED APPLICATION

This application claims the priority benefit of Taiwan application serial no. 112139635, filed on Oct. 17, 2023. The entirety of the above-mentioned patent application is hereby incorporated by reference herein and made a part of this specification.

### BACKGROUND

### Technical Field

The invention relates to a semiconductor structure, and particularly relates to a resistive memory structure.

### Description of Related Art

The resistive memory (e.g., resistive random access memory (RRAM)) structure has the potential advantages such as low power consumption, high-speed operation, and high density, so the resistive memory structure is very suitable as the next-generation memory structure. However, how to further improve the electrical performance (e.g., endurance) of the resistive memory structure is the goal of continuous efforts at present.

### SUMMARY

The invention provides a resistive memory structure, which can have better electrical performance.

The invention provides a resistive memory structure, which includes a transistor device and a resistive memory device. The transistor device includes a gate. The resistive memory device is electrically connected to the gate of the transistor device.

According to an embodiment of the invention, in the resistive memory structure, the transistor device and the resistive memory device may share the gate.

According to an embodiment of the invention, the resistive memory structure may further include a substrate. The transistor device may be located on the substrate. The resistive memory device may be located on the transistor device.

According to an embodiment of the invention, in the resistive memory structure, the transistor device may further include a gate dielectric layer, a first doped region, a second doped region, and a spacer. The gate dielectric layer is located between the gate and the substrate. The first doped region and the second doped region are located in the substrate on two sides of the gate. The spacer is located on the sidewall of the gate and the sidewall of the gate dielectric layer.

According to an embodiment of the invention, in the resistive memory structure, the gate dielectric layer may be a single-layer structure.

According to an embodiment of the invention, in the resistive memory structure, the gate dielectric layer may be a multilayer structure.

According to an embodiment of the invention, in the resistive memory structure, the gate dielectric layer may include a first dielectric layer and a second dielectric layer. The first dielectric layer is located between the gate and the substrate. The second dielectric layer is located between the gate and the first dielectric layer.

According to an embodiment of the invention, in the resistive memory structure, the material of the first dielectric layer may include silicon oxide. The material of the second dielectric layer may include a high dielectric constant (high-k) material.

According to an embodiment of the invention, in the resistive memory structure, the resistive memory device may include the gate, an electrode, and a variable resistance layer. The electrode is located on the gate. The variable resistance layer is located between the electrode and the gate.

According to an embodiment of the invention, in the resistive memory structure, the electrode may be a single-layer structure.

According to an embodiment of the invention, in the resistive memory structure, the electrode may be a multilayer structure.

According to an embodiment of the invention, in the resistive memory structure, the electrode may include a first conductive layer and a second conductive layer. The first conductive layer is located on the gate. The cross-sectional shape of the first conductive layer may include a U-shape. The second conductive layer is located on the first conductive layer.

According to an embodiment of the invention, in the resistive memory structure, the spacer may be further located on the sidewall of the variable resistance layer.

According to an embodiment of the invention, in the resistive memory structure, the variable resistance layer may be a single-layer structure.

According to an embodiment of the invention, in the resistive memory structure, the variable resistance layer may be a multilayer structure.

According to an embodiment of the invention, in the resistive memory structure, the cross-sectional shape of the variable resistance layer may include a U-shape.

According to an embodiment of the invention, in the resistive memory structure, the material of the variable resistance layer may include metal oxide.

According to an embodiment of the invention, in the resistive memory structure, the resistive memory device includes a first electrode, a second electrode, and a variable resistance layer. The first electrode is located on the gate. The first electrode may be electrically connected to the gate. The second electrode is located on the first electrode. The variable resistance layer is located between the second electrode and the first electrode.

According to an embodiment of the invention, the resistive memory structure may further include an interconnect structure. The interconnect structure is located between the first electrode and the gate. The interconnect structure may be electrically connected to the first electrode and the gate.

According to an embodiment of the invention, in the resistive memory structure, the material of the variable resistance layer may include metal oxide.

Based on the above description, in the resistive structure memory according to the invention, the resistive memory device is electrically connected to the gate of the transistor device, thereby improving the electrical performance of the resistive memory structure. For example, when the read operation is performed on the resistive memory structure, since the read current will not pass through the resistive memory device, the endurance of the resistive memory device can be improved. In addition, when the read operation is performed on the resistive memory structure, since the resistive memory structure has a higher ratio of on-current to off-current, the data identification ability can be improved. Furthermore, since the resistive memory device and the transistor device can be effectively integrated, the power consumption of the read operation can be further reduced. On the other hand, the resistive memory structure can effectively prevent the influence of the sneak path.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a resistive memory structure according to some embodiments of the invention.

FIG. 2 is a cross-sectional view of a resistive memory structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

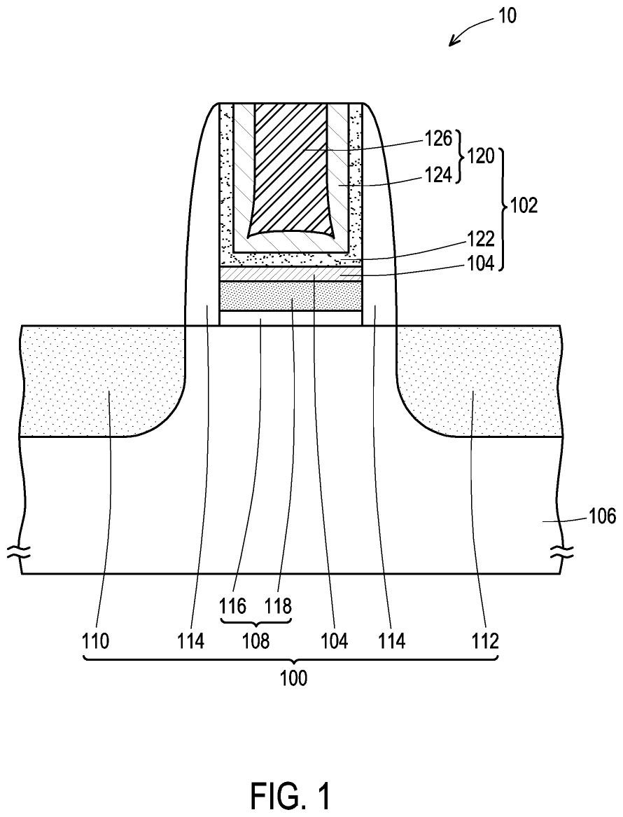

FIG. 1 is a cross-sectional view of a resistive memory structure according to some embodiments of the invention.

Referring to FIG. 1, a resistive memory structure 10 includes a transistor device 100 and a resistive memory device 102. Transistor device 100 includes a gate 104. The gate 104 may be a single-layer structure or a multilayer structure. In some embodiments, the material of the gate 104 may include titanium nitride (TiN), hafnium (Hf), or a combination thereof. The resistive memory device 102 is electrically connected to the gate 104 of the transistor device 100. In the present embodiment, the transistor device 100 and the resistive memory device 102 may share the gate 104, so that the resistive memory device 102 can be electrically connected to the gate 104 of the transistor device 100.

The resistive memory structure 10 may further include a substrate 106. In some embodiments, the substrate 106 may be a semiconductor substrate such as a silicon substrate. The transistor device 100 may be located on the substrate 106. In some embodiments, a portion of the transistor device 100 may be located in the substrate 106. The resistive memory device 102 may be located on the transistor device 100.

The transistor device 100 may further include a gate dielectric layer 108, a doped region 110, a doped region 112, and a spacer 114. The gate dielectric layer 108 is located between the gate 104 and the substrate 106. The gate dielectric layer 108 may be a single-layer structure or a multilayer structure. In the present embodiment, the gate dielectric layer 108 is, for example, a multilayer structure, but the invention is not limited thereto. For example, the gate dielectric layer 108 may include a dielectric layer 116 and a dielectric layer 118. The dielectric layer 116 is located between the gate 104 and the substrate 106. In some embodiments, the material of the dielectric layer 116 may include silicon oxide. The dielectric layer 118 is located between the gate 104 and the dielectric layer 116. In some embodiments, the material of the dielectric layer 118 may include a high dielectric constant material. In other embodiments, the transistor device 100 may not include the dielectric layer 118, and the gate dielectric layer 108 may be a single-layer structure.

The doped region 110 and the doped region 112 are located in the substrate 106 on two sides of the gate 104. The doped region 110 and the doped region 112 may be respectively used as one and the other of a source and a drain. The spacer 114 is located on the sidewall of the gate 104 and the sidewall of the gate dielectric layer 108. The spacer 114 may be a single-layer structure or a multilayer structure. In some embodiments, the material of the spacer 114 may include silicon oxide, silicon nitride, or a combination thereof.

The resistive memory device 102 may include the gate 104, an electrode 120, and a variable resistance layer 122. In some embodiments, the gate 104 may be used as the bottom electrode of the resistive memory device 102, and the electrode 120 may be used as the top electrode of the resistive memory device 102. The electrode 120 is located on the gate 104. The electrode 120 may be a single-layer structure or a multilayer structure. In the present embodiment, the electrode 120 is, for example, a multilayer structure, but the invention is not limited thereto. For example, the electrode 120 may include a conductive layer 124 and a conductive layer 126. The conductive layer 124 is located on the gate 104. The cross-sectional shape of the conductive layer 124 may include a U-shape. The conductive layer 124 may be a single-layer structure or a multilayer structure. In some embodiments, the material of the conductive layer 124 may include titanium nitride, tantalum nitride, titanium, tantalum, hafnium, or a combination thereof. The conductive layer 126 is located on the conductive layer 124. In some embodiments, the material of the conductive layer 126 may include metal such as aluminum or tungsten.

The variable resistance layer 122 is located between the electrode 120 and the gate 104. The cross-sectional shape of the variable resistance layer 122 may include a U-shape. The spacer 114 may be further located on the sidewall of the variable resistance layer 122. The variable resistance layer 122 may be a single-layer structure or a multilayer structure. In some embodiments, the material of the variable resistance layer 122 may include metal oxide. In some embodiments, the material of the variable resistance layer 122 may include hafnium oxide (HfO), tantalum oxide (TaO), titanium oxide (TiO), nickel oxide (NiO), copper oxide (CuO), or a combination thereof.

Based on the above embodiments, in the resistive memory structure 10, the resistive memory device 102 is electrically connected to the gate 104 of the transistor device 100, thereby improving the electrical performance of the resistive memory structure 10. For example, when the read operation is performed on the resistive memory structure 10, since the read current will not pass through the resistive memory device 102, the endurance of the resistive memory device 102 can be improved. In addition, when the read operation is performed on the resistive memory structure 10, since the resistive memory structure 10 has a higher ratio of on-current to off-current, the data identification ability can be improved. Furthermore, since the resistive memory device 102 and the transistor device 100 can be effectively integrated, the power consumption of the read operation can be further reduced. On the other hand, the resistive memory structure 10 can effectively prevent the influence of the sneak path.

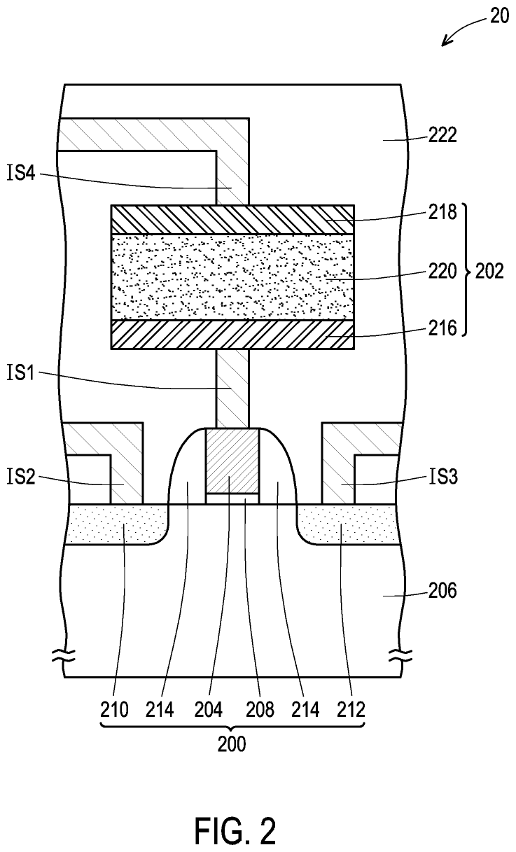

FIG. 2 is a cross-sectional view of a resistive memory structure according to other embodiments of the invention.

Referring to FIG. 2, a resistive memory structure 20 includes a transistor device 200 and a resistive memory device 202. The transistor device 200 includes a gate 204. In some embodiments, the gate 204 includes a polysilicon gate or a metal gate. The resistive memory device 202 is electrically connected to the gate 204 of the transistor device 200. In the present embodiment, the resistive memory structure 20 may further include an interconnect structure IS1. The interconnect structure IS1 is located between the resistive memory device 202 and the gate 204. The interconnect structure IS1 may be electrically connected to the resistive memory device 202 and the gate 204, so that the resistive memory device 202 can be electrically connected to the gate 204 of the transistor device 200. In some embodiments, the interconnect structure IS1 may include a plug, a conductive line, or a combination thereof. In some embodiments, the material of the interconnect structure IS1 may include tungsten, aluminum, copper, titanium, titanium nitride, tantalum, tantalum nitride, or a combination thereof.

The resistive memory structure 20 may further include a substrate 206. In some embodiments, the substrate 206 may be a semiconductor substrate such as a silicon substrate. The transistor device 200 may be located on the substrate 206. In some embodiments, a portion of the transistor device 200 may be located in the substrate 206. The resistive memory device 202 may be located on the transistor device 200.

The transistor device 200 may further include a gate dielectric layer 208, a doped region 210, a doped region 212, and a spacer 214. The gate dielectric layer 208 is located between the gate 204 and the substrate 206. The gate dielectric layer 208 may be a single-layer structure or a multilayer structure. In some embodiments, the material of the gate dielectric layer 208 may include silicon oxide, a high dielectric constant material, or a combination thereof. The doped region 210 and the doped region 212 are located in the substrate 206 on two sides of the gate 204. The doped region 210 and the doped region 212 may be respectively used as one and the other of a source and a drain. The spacer 214 is located on the sidewall of the gate 204 and the sidewall of the gate dielectric layer 208. The spacer 214 may be a single-layer structure or a multilayer structure. In some embodiments, the material of the spacer 214 may include silicon oxide, silicon nitride, or a combination thereof.

The resistive memory device 202 may include an electrode 216, an electrode 218, and a variable resistance layer 220. The electrode 216 is located on the gate 204. In some embodiments, the electrode 216 may be used as the bottom electrode of the resistive memory device 202, and the electrode 218 may be used as the top electrode of the resistive memory device 202. The electrode 216 may be electrically connected to the gate 204. The interconnect structure IS1 is located between the electrode 216 and the gate 204. The interconnect structure IS1 may be electrically connected to the electrode 216 and the gate 204, so that the resistive memory device 202 can be electrically connected to the gate 204 of the transistor device 200. The electrode 216 may be a single-layer structure or a multilayer structure. In some embodiments, the material of the electrode 216 may include titanium nitride, tantalum nitride, titanium, tantalum, hafnium, or a combination thereof.

The electrode 218 is located on the electrode 216. The electrode 218 may be a single-layer structure or a multilayer structure. In some embodiments, the material of the electrode 218 may include titanium nitride, tantalum nitride, titanium, tantalum, hafnium, or a combination thereof.

The variable resistance layer 220 is located between the electrode 218 and the electrode 216. The variable resistance layer 220 may be a single-layer structure or a multilayer structure. In some embodiments, the material of the variable resistance layer 220 may include metal oxide. In some embodiments, the material of the variable resistance layer 220 may include hafnium oxide, tantalum oxide, titanium oxide, nickel oxide, copper oxide, or a combination thereof.

The resistive memory structure 20 may further include an interconnect structure IS2, an interconnect structure IS3, and an interconnect structure IS4. The interconnect structure IS2, the interconnect structure IS3, and the interconnect structure IS4 may be electrically connected to the doped region 210, the doped region 212, and the electrode 218 respectively. In some embodiments, the interconnect structure IS2, the interconnect structure IS3, and the interconnect structure IS4 may include plugs, conductive lines, or combinations thereof. In some embodiments, the material of the interconnect structure IS2, the material of the interconnect structure IS3, and the material of the interconnect structure IS4 may include tungsten, aluminum, copper, titanium, titanium nitride, tantalum, tantalum nitride, or combinations thereof.

The resistive memory structure 20 may further include a dielectric layer 222. The dielectric layer 222 may cover the transistor device 200. The resistive memory device 202, the interconnect structure IS1, the interconnect structure IS2, the interconnect structure IS3, and the interconnect structure IS4 may be located in the dielectric layer 222. In some embodiments, the dielectric layer 222 may be a multilayer structure. In some embodiments, the material of the dielectric layer 222 may include silicon oxide.

Based on the above embodiments, in the resistive memory structure 20, the resistive memory device 202 is electrically connected to the gate 204 of the transistor device 200, thereby improving the electrical performance of the resistive memory structure 20. For example, when the read operation is performed on the resistive memory structure 20, since the read current will not pass through the resistive memory device 202, the endurance of the resistive memory device 202 can be improved. In addition, when the read operation is performed on the resistive memory structure 20, since the resistive memory structure 20 has a higher ratio of on-current to off-current, the data identification ability can be improved. Furthermore, since the resistive memory device 202 and the transistor device 200 can be effectively integrated, the power consumption of the read operation can be further reduced. On the other hand, the resistive memory structure 20 can effectively prevent the influence of the sneak path.

In summary, in the resistive memory structure of the aforementioned embodiments, the resistive memory device is electrically connected to the gate of the transistor device, thereby improving the electrical performance of the resistive memory structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A resistive memory structure, comprising:
a transistor device comprising a gate; and
a resistive memory device electrically connected to the gate of the transistor device.

2. The resistive memory structure according to claim 1, wherein the transistor device and the resistive memory device share the gate.

3. The resistive memory structure according to claim 1, further comprising:
a substrate, wherein
the transistor device is located on the substrate, and
the resistive memory device is located on the transistor device.

4. The resistive memory structure according to claim 3, wherein the transistor device further comprises:
a gate dielectric layer located between the gate and the substrate;
a first doped region and a second doped region located in the substrate on two sides of the gate; and
a spacer located on a sidewall of the gate and a sidewall of the gate dielectric layer.

5. The resistive memory structure according to claim 4, wherein the gate dielectric layer comprises a single-layer structure.

6. The resistive memory structure according to claim 4, wherein the gate dielectric layer comprises a multilayer structure.

7. The resistive memory structure according to claim 4, wherein the gate dielectric layer comprises:
a first dielectric layer located between the gate and the substrate; and
a second dielectric layer located between the gate and the first dielectric layer.

8. The resistive memory structure according to claim 7, wherein a material of the first dielectric layer comprises silicon oxide, and a material of the second dielectric layer comprises a high dielectric constant material.

9. The resistive memory structure according to claim 4, wherein the resistive memory device comprises:
the gate;
an electrode located on the gate; and
a variable resistance layer located between the electrode and the gate.

10. The resistive memory structure according to claim 9, wherein the electrode comprises a single-layer structure.

11. The resistive memory structure according to claim 9, wherein the electrode comprises a multilayer structure.

12. The resistive memory structure according to claim 9, wherein the electrode comprises:
a first conductive layer located on the gate, wherein a cross-sectional shape of the first conductive layer comprises a U-shape; and
a second conductive layer located on the first conductive layer.

13. The resistive memory structure according to claim 9, wherein the spacer is further located on a sidewall of the variable resistance layer.

14. The resistive memory structure according to claim 9, wherein the variable resistance layer comprises a single-layer structure.

15. The resistive memory structure according to claim 9, wherein the variable resistance layer comprises a multilayer structure.

16. The resistive memory structure according to claim 9, wherein a cross-sectional shape of the variable resistance layer comprises a U-shape.

17. The resistive memory structure according to claim 9, wherein a material of the variable resistance layer comprises metal oxide.

18. The resistive memory structure according to claim 1, wherein the resistive memory device comprises:
a first electrode located on the gate and electrically connected to the gate;
a second electrode located on the first electrode; and
a variable resistance layer located between the second electrode and the first electrode.

19. The resistive memory structure according to claim 18, further comprising:
an interconnect structure located between the first electrode and the gate and electrically connected to the first electrode and the gate.

20. The resistive memory structure according to claim 18, wherein a material of the variable resistance layer comprises metal oxide.
